(19) United States
(12) Patent Application Publication
(10) Pub. No.: US 2025/0261342 A1
(43) Pub. Date: Aug. 14, 2025

(54) Moving Vehicle-Mounted Gimbal Platform Having a Heat Dissipating Columnar Housing

(71) Applicant: Lumos Technology Co., Ltd., Taipei (TW)

(72) Inventor: Chih-Yi Yang, Taipei (TW)

(21) Appl. No.: 19/025,879

(22) Filed: Jan. 16, 2025

Related U.S. Application Data
(60) Provisional application No. 63/553,011, filed on Feb. 13, 2024.

(51) Int. Cl. H05K 7/20; G03B 15/02; G03B 17/08; G03B 17/55; G03B 17/56; G03B 30/00

(52) U.S. Cl. CPC H05K 7/20509; G03B 15/02; G03B 17/08; G03B 17/55; G03B 17/561; G03B 30/00; H05K 7/20327; H05K 7/20336; H05K 7/2049

(57) ABSTRACT

A moving carrier-mounted gimbal platform which accommodates a light emitter/photodetector, the light emitter/photodetector having a lens; the moving carrier-mounted gimbal platform includes: a base, a heat dissipating columnar housing, a heat conductor, and a heat pipe; the heat dissipating columnar housing includes a thermally conductive hollow metallic tube in which the light emitter/photodetector is accommodated and a closure; the thermally conductive hollow metallic tube being formed with two opposite end openings; the heat conductor tightly engages the light emitter/photodetector; the heat pipes thermally conductively tightly engage the heat conductor; portions of respective heat pipes distal from the heat conductor thermally conductively tightly engaging the heat dissipating columnar housing.

### FIELD

The subject matter described herein relates to a moving carrier-mounted gimbal platform, and more particularly relates to a moving vehicle-mounted gimbal platform having a heat dissipating columnar housing.

### BACKGROUND

In recent years, aircrafts like drones are widely applied in areas such as road traffic monitor, aerial pesticide spray, fixed equipment inspection, and even battlefield situation awareness, attack, and defense, as well as the brewing flying taxis services for transporting passengers. All of such application areas would have basic requirements on ambient environment perception and collision avoidance. In addition, moving vehicles like autonomous vehicles would also rely on reliable environment perception. Particularly, such vehicle-mounted image sensors including cameras are always disposed at positions exposed to the outer sides of the aircrafts or moving vehicles, which would be tested by severe weathers; to prevent rainwater and dusts from accessing their insides, their housings need to be sealed, giving rise to a heat dissipation issue that should be considered.

As illustrated in FIG. 1, a chip used in an image acquisition device is usually highly sensitive to the operating environment; once the ambient temperature rises from the room temperature to for example 40° C., the dark current would multiply; and even without any real light illumination, temperature-activated leakage current would still occur to a photosensor; if the temperature further rises by 20° C., the leakage current would also further multiply, rapidly degrading image quality.

On the other hand, light emitters such as laser are also notably influenced by the operating environment temperature. As illustrated in FIG. 2, with a luminescent intensity at for example 150° C. as a reference, when the temperature rises by 30° C., the luminescent intensity would be halved; if the temperature rises by 70° C., the luminescent intensity would only have about 20% left. Therefore, if the moving carrier emits a laser light for optical detection, the operating environment temperature of the light emitter is also an important factor to consider.

However, due to limitation of the electrical capacity of the moving vehicle itself, the power distributed to the accessories such as the image acquisition device which needs heat dissipation is limited, which cannot be as generous as the scenarios of being powered by mains electricity. Therefore, the image acquisition device should be cooled with as least energy consumption as possible, so that the cooling issue is rather knotty. FIG. 3 illustrates a stereoscopic diagram of a conventional gimbal platform 9. The U.S. patents U.S. Pat. No. 11,150,025 B2 and US20130000881 A1 have provided solutions to the cooling issue. However, the solution described in U.S. Pat. No. 11,150,025 B2 has a complex internal structure; the overall structure thereof is separately designed and developed to meet specific individual needs, which cannot be universalized to different fields. The patent US20130000881 A1 leverages an additional fan to blow in a gas, so that the internal heat is carried out via passage designs of the internal structure to the housing to thereby realize heat dissipation, which has a complex internal structure; in addition, the structural design of the air passages gives rises to a large footprint of the overall structure; moreover, it also requires additional provision of a fan.

Hereinafter, the detailed features and advantages of the disclosure will be described through the embodiments, the contents of which suffice for those skilled in the art to understand the technical contents of the disclosure and implement the disclosure based on the contents; and the relevant objectives and advantages of the disclosure may be easily understood by those skilled in the art based on the contents in the description, the claims, and the drawings.

### SUMMARY

A moving carrier-mounted gimbal platform having a heat dissipating columnar housing is described herein, which effectively enhances a cooling effect of a light emitter/photodetector mounted on the moving carrier.

A moving carrier-mounted gimbal platform having a heat dissipating columnar housing is described herein, the overall structure of which is simple with effectively controlled size, so that the entirety of the gimbal platform does not occupy much space.

A moving carrier-mounted gimbal platform having a heat dissipating columnar housing is described herein, which is universally adapted to different camera equipment and not limited to structural designs.

The disclosure provides a moving carrier-mounted gimbal platform, the moving carrier-mounted gimbal platform being configurable to accommodate at least one light emitter/photodetector, the light emitter/photodetector having at least one lens, wherein the moving carrier-mounted gimbal platform comprises: at least one base which is mounted to a moving carrier and enabled by the moving carrier to actuate the light emitter/photodetector, and configured to communicate signals between the light emitter/photodetector and the moving carrier; at least one heat dissipating columnar housing mounted to the base, the heat dissipating columnar housing comprising a thermally conductive hollow metallic tube extending in a lengthwise direction and at least one closure, wherein the light emitter/photodetector is accommodated in the thermally conductive hollow metallic tube, the thermally conductive hollow metallic tube being formed with two opposite end openings in the lengthwise direction, the closure being configured to seal at least one of the end openings; at least one heat conductor tightly engaging the light emitter/photodetector; and a plurality of heat pipes thermally conductively tightly engaging the heat conductor, portions of respective heat pipes distal from the heat conductor being thermally conductively tightly engaging the heat dissipating columnar housing.

According to one implementation of the disclosure, the light emitter/photodetector is arranged in the lengthwise direction, and the lens is disposed facing the end opening opposite the closure.

According to one implementation of the disclosure, the heat pipes are clamped to tightly engage the heat conductor; the heat conducting hollow metallic tube is an extruded aluminum tube formed with a plurality of elongated slots on its inner sidewall, portions of respective heat pipes distal from where they are clamped are formed of cooling segments corresponding to respective elongated slots; the heat dissipating columnar housing further comprises a thermally conductive bonding agent configured to securely bond the cooling segments to the elongated slots when the cooling segments are disposed in the elongated slots; and a sealed light transmissive element is arranged at the end opening which the lens faces.

According to one implementation of the disclosure, the heat dissipating columnar housing comprises two closures which are configured to seal the two end openings, and the thermally conductive hollow metallic tube is formed with at least one through hole for the lens of the light emitter/photodetector to capture an image outside.

According to one implementation of the disclosure, the heat conductor further comprises a substrate, an intermediate clamp, and a plurality of internal-layer heat pipes in thermally conductive engagement with the substrate and the intermediate clamp; the heat pipes are clamped to tightly engage the intermediate clamp; the thermally conductive hollow metallic tube is an extruded aluminum tube having a plurality of elongated slots formed on its inner sidewall; portions of respective heat pipes distal from where they are clamped are formed of cooling segments corresponding to respective elongated slots; the heat dissipating columnar housing further comprises a thermally conductive bonding agent configured to securely bond the cooling segments to the elongated slots when the cooling segments are disposed in the elongated slots.

According to one implementation of the disclosure, the base has a bottom side, and two lateral sides perpendicular to the bottom side; the moving carrier-mounted gimbal platform comprises two heat dissipating columnar housings mounted at the two lateral sides of the base, respectively.

According to one implementation of the disclosure, the heat dissipating columnar housing further comprises a thermoelectric device, the thermoelectric device having a heating side surface and a cooling side surface, the heating side surface facing the heat pipes thermally conductively tightly engaging the heat dissipating columnar housing.

According to one implementation of the disclosure, the heat dissipating columnar housing is formed with at least one drain hole, and the heat dissipating columnar housing further comprises a water catchment element corresponding to the cooling side surface of the thermoelectric device and a drain element corresponding to the water catchment element, the drain element being disposed passing through the drain hole.

### BRIEF DESCRIPTION OF THE DRAWINGS

FIG. 1 is a line graph of temperature-influenced dark current (mV) of an image acquisition device, illustrating that the image acquisition device is strongly influenced by operating environment temperature.

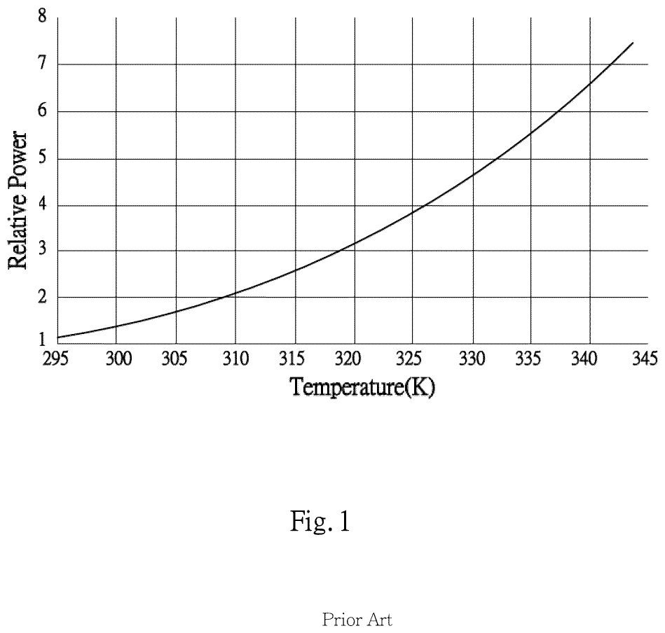

FIG. 2 is a line graph of a relationship between luminescent intensity and operating environment temperature of a known laser element.

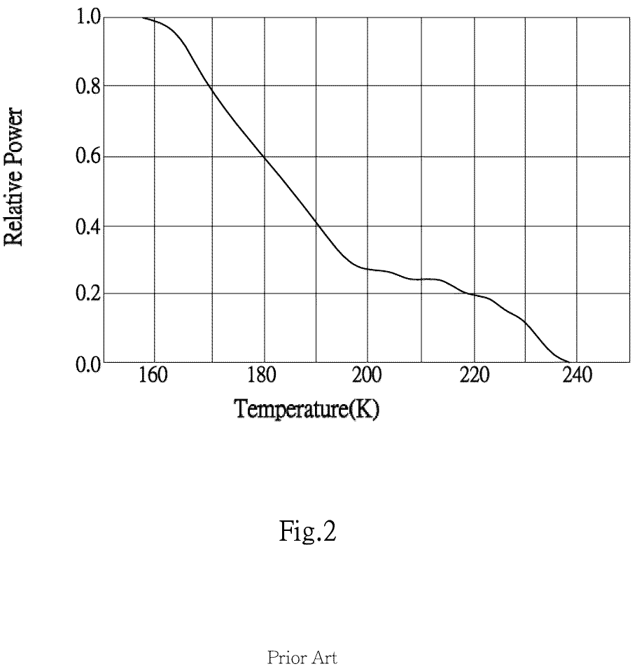

FIG. 3 is a stereoscopic diagram of setup of a known moving carrier-mounted gimbal platform.

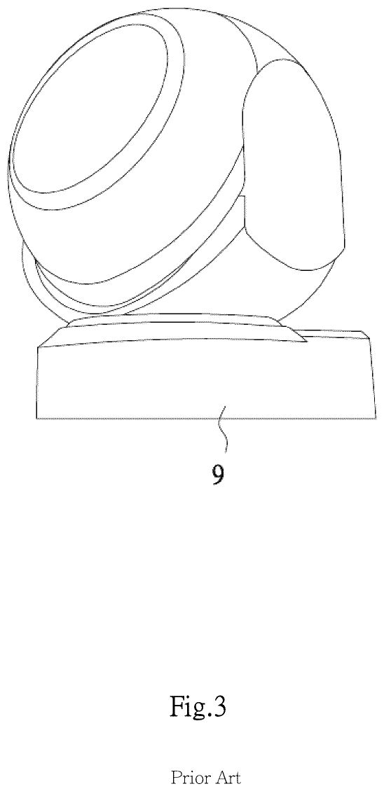

FIG. 4 is a stereoscopic exploded view of a moving carrier-mounted gimbal platform having a heat dissipating columnar housing according to a first implementation of the disclosure, where an image acquisition device is arranged in a thermally conductive hollow metallic tube along a lengthwise direction.

FIG. 5 is a structural positional diagram of tight engagement of heat pipes with the heat dissipating columnar housing according to the implementation of FIG. 4.

FIG. 6 is a planar positional diagram of a mounting position of the image acquisition device in the thermally conductive hollow metallic tube along the lengthwise direction in the implementation of FIG. 4.

FIG. 7 is a setup schematic diagram of a moving carrier-mounted gimbal platform having the heat dissipating columnar housing according to a second implementation of the disclosure, where the heat dissipating columnar housing is mounted at one lateral side of a base.

FIG. 8 is structural exploded view of disposing a lens of an image acquisition device in a through hole on a side surface of a thermally conductive hollow metallic tube in the implementation of FIG. 7.

FIG. 9 is a structural schematic diagram of a condensate drain setup of the moving carrier-mounted gimbal platform having a heat dissipating columnar housing according to a third implementation of the disclosure.

FIG. 10 is a structural sectional view of the moving carrier-mounted gimbal platform having a heat dissipating columnar housing according to a fourth implementation of the disclosure.

### DETAILED DESCRIPTION OF EMBODIMENTS

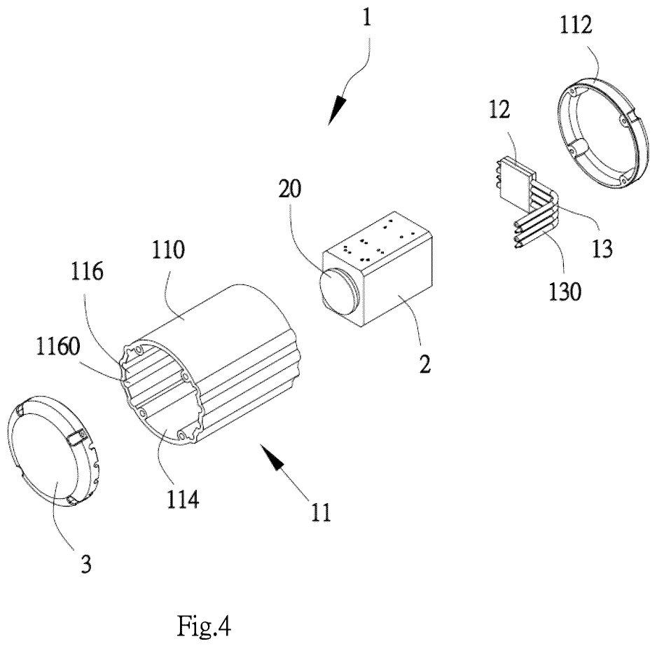

FIGS. 4 through 6 illustrate a moving carrier-mounted gimbal platform having a heat dissipating columnar housing according to a first implementation of the disclosure. The moving carrier-mounted gimbal platform described herein is set up on a moving carrier such as a vehicle, an aircraft, a train, a drone, and even a loitering munition. The moving carrier-mounted gimbal platform 1 in its entirety is mounted on the moving carrier, configured to accommodate at least one light emitter/photodetector 2. In this implementation, the light emitter/photodetector 2 is exemplarily a camera having at least one lens 20; the moving carrier-mounted gimbal platform 1 comprises: a base, a heat dissipating columnar housing 11, a heat conductor 12, and a plurality of heat pipes 13. In this implementation, the base, which is mounted to the moving carrier and enabled by the moving carrier to actuate the light emitter/photodetector 2, is also configured to communicate signals between the light emitter/photodetector 2 and the moving carrier, i.e., the base may be enabled to actuate the light emitter/photodetector 2 and communicate signals via a slip ring or any wired or wireless connection, whereby image signals acquired by the camera are backhauled to a processor (not shown) in the moving carrier for analysis.

The base is mainly configured to mount the heat dissipating columnar housing 11, the heat dissipating columnar housing 11 comprising a thermally conductive hollow metallic tube 110 extended in a lengthwise direction and at least one closure 112. To simplify the structure for ease of manufacturing and improve thermal conductivity of the thermally conductive hollow metallic tube, this implementation uses an extruded aluminum tube as an example. Since the aluminum material is subjected to plastic deformation at a low softening point and an aluminum oxide (Al₂O₃) protective layer may be automatically formed when the formed aluminum tube is exposed to air, the thermally conductive property of the metallic tube body is ensured; particularly, since the shape of the aluminum tube body is fixed in the lengthwise direction, its length may be set as needed, which facilitates standardized manufacturing and is flexible to design. The thermally conductive hollow metallic tube 110 is formed with two opposite end openings 114 in the lengthwise direction, and the light emitter/photodetector 2 may be accommodated inside the tube body. In this implementation, the lens 20 of the light emitter/photodetector 2 is disposed facing one of the end openings 114, while the closure 112 is configured to seal the end opening 114 opposite the lens 20.

To ease the description, a side surface of the camera opposite the lens 20 is referred to as a bottom surface, and the heat conductor 12 tightly engages the bottom surface of the light emitter/photodetector 2, whereby heat created by a circuit board mounted with for example a light sensor or a controller can be sufficiently conducted out. In this implementation, the heat conductor 12 clamps respective heat pipes 13 via two metallic sheets, so that the heat pipes 13 in their entireties are thermally conductively tightly bonded to the heat conductor 12; the portions of the heat pipes distal from the heat conductor 12 thermally conductively tightly engage an inner sidewall of the heat dissipating columnar housing 11.

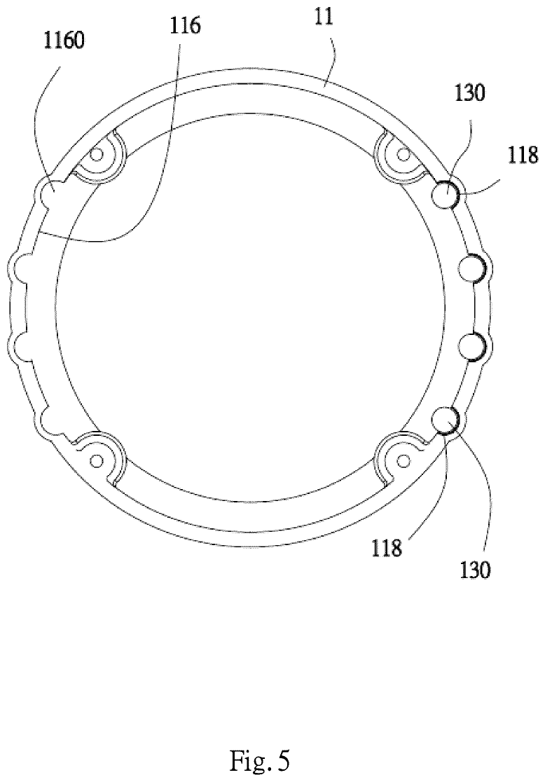

The thermally conductive hollow metallic tube 110 is exemplarily made of aluminum and has a fixed cross-sectional profile in this implementation. It may be seen from FIG. 5 that, the softened aluminum material is extruded into a designed mold so that the extruded bars have a same cross-sectional profile; therefore, a plurality of elongated slots 1160 are smoothly formed on an inner sidewall 116 of the thermally conductive hollow metallic tube 110. To ease the description, a portion of the heat pipe 13 distal from the heat conductor 12 is defined as a cooling segment 130. The cooling segment 130 is inserted in a corresponding elongated slot 1160, and then a thermally conductive bonding agent 118 is applied and cured, the thermally conductive bonding agent 118 serving to securely bond the cooling segment 120 in the elongated slot 1160; meanwhile, the thermally conductive bonding agent 118 plays a role of optimizing and ensuring thermal conduction. Additionally, the end opening 114 the lens 20 faces is provided with a sealed light transmissible element 3, which not only plays a role of sealing, but also enables the lens 20 to clearly capture an image outside.

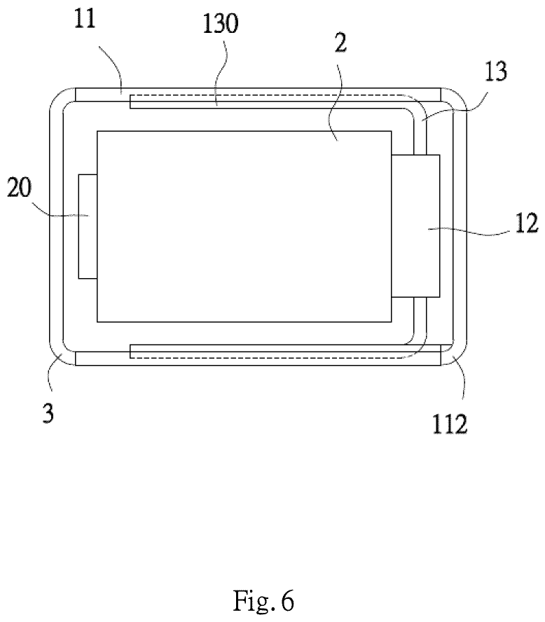

As illustrated in FIG. 6, after the base, the heat dissipating columnar housing 11, the heat conductor 12, and the plurality of heat pipes 13 are assembled, the heat conductor 12 is disposed at a rear end of the light emitter/photodetector 2 and tightly engaged therewith, so that heat created by the camera is directly transferred to the heat conductor 12, while the heat pipes 13 thermally conductively tightly engage the heat conductor 12 conduct the heat from the heat conductor 12 to the heat dissipating columnar housing 11. As illustrated in the figure, the heat pipes 13, which are bent in a cornered structure, are directly tightly pressed by the heat conductor 12 against the heat dissipating columnar housing 11; the simply bent and assembled manner of the heat pipes 13 allows for the heat to be conducted to the heat dissipating columnar housing 11 as rapidly as possible, thereby effectively enhancing the cooling effect; in addition, due to the simple overall structure and effective size control, the gimbal platform has a reduced footage; in particular, since the profile of the extruded aluminum is variable with the mold, the metallic tube can be formed with a round or square profile dependent on client demands so long as its lengthwise direction is uniform; moreover, since the structure itself has an optimum water-proof effect with enhanced product reliability, the housing can be adapted to cameras of different sizes, without being limited by structural designs.

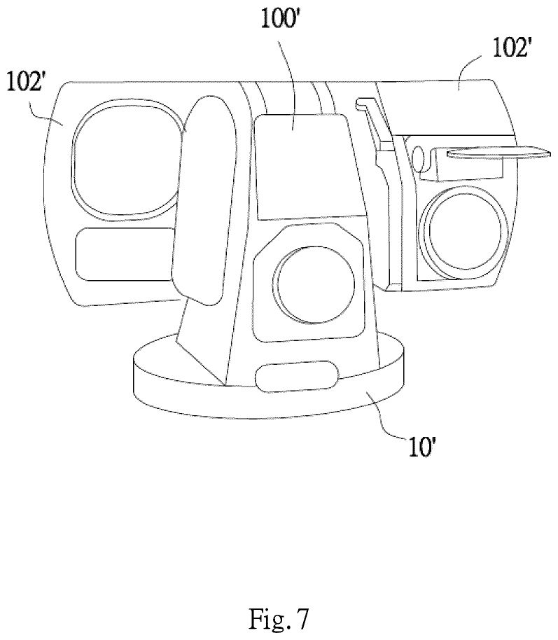

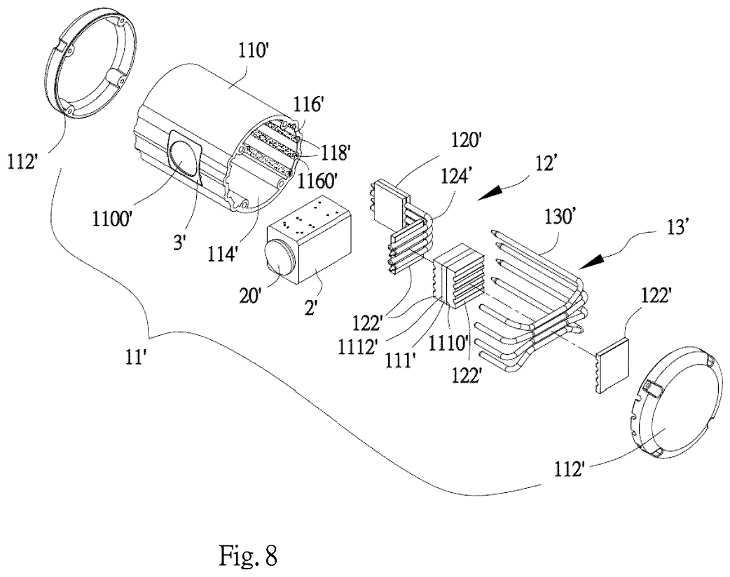

FIGS. 7 and 8 illustrate a second implementation of the moving carrier-mounted gimbal platform having a heat dissipating columnar housing according to the disclosure. In this implementation, the structure of the base 10′ is different from the first implementation, where a bottom side 100′ of the base 10′ is mounted to the moving carrier, while two lateral sides 102′ perpendicular to the bottom side 100′ are configured to mount corresponding devices. In this implementation, only one of the two lateral sides 102′ of the base 10′ is illustrated, which is configured to mount a heat dissipating columnar housing 11′; or both lateral sides 102′ may be mounted with a heat dissipating columnar housing 11′ dependent on needs. Moreover, in this implementation, the heat dissipating columnar housing 11′ may pivot relative to the base 10′ in a pitching direction, while the base 10′ may rotate about the moving carrier in a paper surface up-down direction as an axis, whereby a three-dimensional image is captured.

In this implementation, the light emitter/photodetector 2′ is arranged in the heat dissipating columnar housing 11′ in a direction substantially perpendicular to the lengthwise direction of the latter; the heat dissipating columnar housing 11′ comprises two closures 112′ which are configured to seal two end openings 114′, at least one through hole 1100′ is provided in a substantially central portion of the thermally conductive hollow metallic tube 110′ of the heat dissipating columnar housing 11′, and a sealed light transmissive element 3′ is provided at the position where the through hole 1100′ is provided, playing a role of sealing while allowing for the lens 20′ to clearly capture an image outside.

In this implementation, the heat conductor 12′ tightly engaging the light emitter/photodetector 2′ has an inner-layer conduction setup, comprising: a substrate 120′, an intermediate clamp 122′, and a plurality of internal-layer heat pipes 124′, two ends of each internal-layer heat pipe 124′ being thermally conductively engaged with the substrate 120′ and the intermediate clamp 122′, respectively, the substrate 120′ being tightly snugly fitted to the underside of the light emitter/photodetector 2′, the internal-layer heat pipe 124′ being bent substantially vertically between its two ends, the opposite ends of the internal-layer heat pipe 124′ engaged with the substrate 120′ being securely tightly clamped by intermediate clamps 122′; in addition, the engagement manner between the heat pipes 13′ and the thermally conductive hollow metallic tube 110′ is identical to that described in the preceding implementation, i.e., one end of each heat pipe 13′ is securely clamped by the intermediate clamp 122′. A plurality of elongated slots 1160′ are likewise formed on an inner sidewall 116′ of the thermally conductive hollow metallic tube 110′, the cooling segment 130′ of each heat pipe 13′ distal from the intermediate clamp 122′ being correspondingly disposed in the corresponding elongated slot 1160′, a thermally conductive bonding agent 118′ being applied in the elongated slot 1160′ to optimize heat conduction. In this implementation, the heat pipes comprise internal-layer pipes and external-layer pipes, heat being conducted from inside to outside via an intermediate heat conduction layer, so that respective layers of heat pipes are only simply bent without complex curves, which ensures vaporization of the phase change material inside the heat pipes and facilitates backflow of condensate moisture.

On the other hand, the heat dissipating columnar housing 11′ further comprises a thermoelectric device 111″; since the intermediate clamp 122′ in this implementation is formed of a multi-layer structure, the thermoelectric device 111′ is arranged between the intermediate clamp 122′ clamping the internal-layer heat pipe 124′ and the intermediate clamp 122′ clamping the heat pipe 13′. The thermoelectric device 111′ has a heating side surface 1110′ and a cooling side surface 1112′, the heating side surface 1110′ thermally conductively tightly engaging the heat pipes 13′ of the heat dissipating columnar housing 11′; when heat created by the light emitter/photodetector 2′ is conducted to the intermediate clamp 122′ via the internal-layer heat pipes 124′ and correspondingly accesses the cooling side surface 1112′ of the thermoelectric device 111′, heat can be absorbed faster, and then the heat is conducted from the heating side surface 1110′ of the thermoelectric device 111′ to the heat dissipating columnar housing 11′ via the heat pipes 13′, whereby an entire cooling-heating cycle is completed, further effectively enhancing the cooling effect.

Particularly, in this implementation, a laser element as a light emitter may be mounted at one of the two lateral sides, and a camera as a light receiver may be mounted at the opposite lateral side, whereby the acquisition success rate and resolution of optical images can be enhanced, which particularly ensures sound operation of the light emitter and the light receiver. However, as those skilled in the art can easily appreciate, although the preceding implementations mainly use a camera as an example, the gimbal platform described herein can also be applied in a case that the light emitter is separately mounted on the moving carrier and an optical modulator such as a lens is mounted in front of the light emitter, which also ensures a sound operating environment to such temperature-sensitive optical elements.

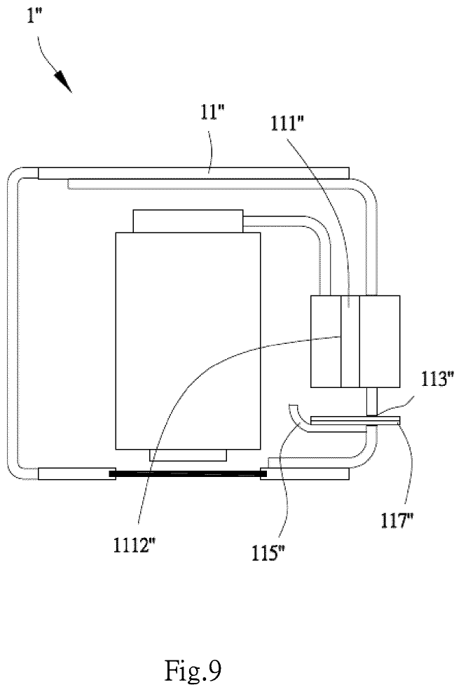

FIG. 9 illustrates a third implementation of the moving carrier-mounted gimbal platform having a heat dissipating columnar housing. The internal electronic devices such as a camera create heat, which would lower the relative humidity inside the gimbal platform; however, after the heat is continuously dissipated out, the temperature drop in the internal environment would raise the relative humidity, while the continuous humidity rise over a long time in the operating environment would compromise the service life and reliability of the electronic components. Conventional dehumidification manners include moisture absorption by a drying agent, dehumidification by a compressor, and raising temperature to increase saturated vapor pressure of the moisture. Unfortunately, due to limited accommodation capacity, the drying agent cannot last long, while the compressor is not only energy-consuming, but also installable due to size restriction of the gimbal platform; although the manner of raising the saturated vapor pressure by temperature rise is convenient and easily implemented, it is contradictory to the objective of lowering the operating environment temperature of the disclosure.

Therefore, inheriting the structural design of the thermoelectric device in the second implementation, a moving carrier-mounted gimbal platform 1″ in this third implementation is formed with at least one drain hole 113″ on the heat dissipating columnar housing 11″, a water catchment element 115″ is arranged inside the heat dissipating columnar housing 11″, and a drain element 117″ is mounted in the drain hole 113″; the drain element 117″, e.g., a capillary tube, is disposed such that one end thereof passes through the drain hole 113″ and an opposite end thereof is positioned at the water catchment element 115″; the water caught in the water catchment element 115″ is drained out of the drain hole 113″ under the capillary action; since the water catchment element 115″ is disposed at the cooling side surface 1112″ corresponding to the thermoelectric device 111′″, the moisture in the surrounding air with a low temperature and a high relative humidity is condensed by the low temperature of the cooling side surface 1112″ and drained from the water catchment element 115″ out of the gimbal platform under the capillary action. All of such structures are conventional designs, which can solve the problem of relative humidity rise in the inside due to temperature drop of the operating environment without consumption of extra electricity.

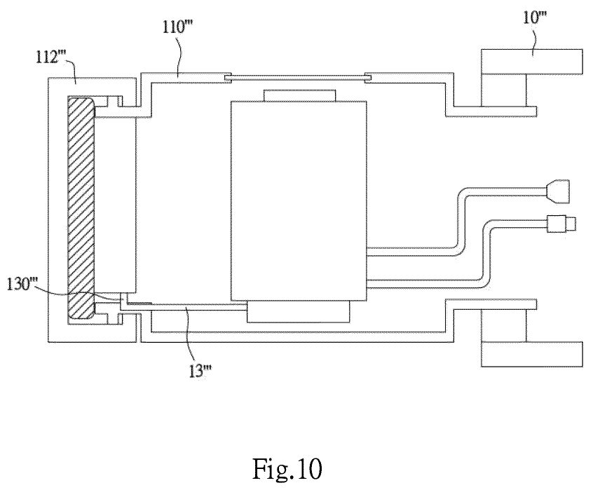

Of course, as those skilled in the art would easily understand, although the heat pipes in the preceding implementations are thermally conductively tightly engaged with the thermally conductive hollow metallic tube, the disclosure is not limited to the preceding engagement manners. As illustrated in the fourth implementation of the disclosure shown in FIG. 10, when the thermally conductive hollow metallic tube 110′″ engages the base 10′″ in the manner shown in the right side of the figure, the closure 112′″ at the left side distal from the base may exchange heat with the thermally conductively tightly engaged cooling segment 130′″ of the heat pipe 13′″ via a thermally conductive fluid (not shown) as the thermally conductive medium, whereby the heat created by the light emitter/photodetector can be conducted out to the left side of the figure and dissipated therefrom.

The implementations described supra exemplarily illustrate the principle and effects of the disclosure, not intended for limiting the disclosure. Those skilled in the art may modify the implementations without departing from the spirits and scope of the disclosure. Therefore, the extent of protection of the disclosure shall be defined by the appending claims.

I/We claim:

1. A moving carrier-mounted gimbal platform, the moving carrier-mounted gimbal platform being configurable to accommodate at least one light emitter/photodetector, the light emitter/photodetector having at least one lens, wherein the moving carrier-mounted gimbal platform comprises:
at least one base which is mounted to a moving carrier and enabled by the moving carrier to actuate the light emitter/photodetector, and configured to communicate signals between the light emitter/photodetector and the moving carrier;
at least one heat dissipating columnar housing mounted to the base, the heat dissipating columnar housing comprising a thermally conductive hollow metallic tube extending in a lengthwise direction and at least one closure, wherein the light emitter/photodetector is accommodated in the thermally conductive hollow metallic tube, the thermally conductive hollow metallic tube being formed with two opposite end openings in the lengthwise direction, the closure being configured to seal at least one of the end openings;
at least one heat conductor tightly engaging the light emitter/photodetector; and
a plurality of heat pipes thermally conductively tightly engaging the heat conductor, portions of respective heat pipes distal from the heat conductor being thermally conductively tightly engaging the heat dissipating columnar housing.

2. The moving carrier-mounted gimbal platform according to claim 1, wherein the light emitter/photodetector is arranged in the lengthwise direction, and the lens is disposed facing the end opening opposite the closure.

3. The moving carrier-mounted gimbal platform according to claim 2, wherein the heat pipes are clamped to tightly engage the heat conductor; the heat conducting hollow metallic tube is an extruded aluminum tube formed with a plurality of elongated slots on its inner sidewall, portions of respective heat pipes distal from where they are clamped are formed of cooling segments corresponding to respective elongated slots; the heat dissipating columnar housing further comprises a thermally conductive bonding agent configured to securely bond the cooling segments to the elongated slots when the cooling segments are disposed in the elongated slots; and a sealed light transmissive element is arranged at the end opening which the lens faces.

4. The moving carrier-mounted gimbal platform according to claim 1, wherein the heat dissipating columnar housing comprises two closures which are configured to seal the two end openings, and the thermally conductive hollow metallic tube is formed with at least one through hole for the lens of the light emitter/photodetector to capture an image outside.

5. The moving carrier-mounted gimbal platform according to claim 4, wherein the heat conductor further comprises a substrate, an intermediate clamp, and a plurality of internal-layer heat pipes in thermally conductive engagement with the substrate and the intermediate clamp; the heat pipes are clamped to tightly engage the intermediate clamp; the thermally conductive hollow metallic tube is an extruded aluminum tube having a plurality of elongated slots formed on its inner sidewall; portions of respective heat pipes distal from where they are clamped are formed of cooling segments corresponding to respective elongated slots; the heat dissipating columnar housing further comprises a thermally conductive bonding agent configured to securely bond the cooling segments to the elongated slots when the cooling segments are disposed in the elongated slots.

6. The moving carrier-mounted gimbal platform according to claim 1, wherein the base has a bottom side, and two lateral sides perpendicular to the bottom side; the moving carrier-mounted gimbal platform comprises two heat dissipating columnar housings mounted at the two lateral sides of the base, respectively.

7. The moving carrier-mounted gimbal platform according to claim 1, wherein the heat dissipating columnar housing further comprises a thermoelectric device, the thermoelectric device having a heating side surface and a cooling side surface, the heating side surface facing the heat pipes thermally conductively tightly engaging the heat dissipating columnar housing.

8. The moving carrier-mounted gimbal platform according to claim 7, wherein the heat dissipating columnar housing is formed with at least one drain hole, and the heat dissipating columnar housing further comprises a water catchment element corresponding to the cooling side surface of the thermoelectric device and a drain element corresponding to the water catchment element, the drain element being disposed passing through the drain hole.
